(19) United States
(12) Patent Application Publication
(10) Pub. No.: US 2004/0266132 A1
(43) Pub. Date: Dec. 30, 2004

(54) Method of forming device isolation film in semiconductor device

(76) Inventor: Cha Deok Dong, Ichon-Shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/720,457

(22) Filed: Nov. 24, 2003

(30) Foreign Application Priority Data
Jun. 27, 2003 (KR) 2003-42420

(51) Int. Cl. H01L 21/76

(52) U.S. Cl. 438/424; 438/433

(57) ABSTRACT

The present invention relates to a method of forming a device isolation film in a semiconductor device. The present invention comprises the steps of; performing an ion implantation for controlling a threshold voltage on a surface of a semiconductor substrate; forming a trench to define an active region and a device isolation region by performing a photolithography process on the semiconductor substrate; performing an oxidation process for extremely prohibiting ions, which are implanted to control the threshold voltage, from diffusing to the device isolation region and forming a side wall oxidation film at the side wall of the trench; performing an ion implantation on the active region to compensate for ions for controlling the threshold voltage, which are diffused from the active region to the side wall oxidation film by the oxidation process; and forming a device isolation film by burying the oxidation film inside the trench.

Therefore, by lowering a processing temperature of the oxidation process to form the side wall oxidation film to the trench, and performing an ion implantation process for compensating for ions which are diffused to the side wall oxidation film at the oxidation process, ion concentration distribution of a region on which ions for controlling a threshold voltage are implanted can be constant, whereby a performance of a device can be improved.

### BACKGROUND

1. Field of the Invention

The present invention relates to a method of forming a device isolation film in a semiconductor device.

2. Discussion of Related Art

General process of forming a device isolation film in a semiconductor device comprises the steps of forming a photoresist pattern for forming a device isolation film in the predetermined region on a semiconductor substrate and forming a trench through performing an etching process by using the pattern as a mask. At this time, in order to compensate for etching damage that occurred during the etching process, and to increase an adhesive strength of an oxidation film to be buried inside the trench, an oxidation process for forming a side wall oxidation film at the side wall of the formed trench is performed, while a rounding treatment of an upper portion or a bottom corner of the trench is performed.

At this time, on the semiconductor substrate, an ion implantation is performed to control a threshold voltage through an ion implantation process before a process of forming the device isolation film, but there is a phenomenon that ions implanted during the ion implantation process for controlling the threshold voltage are diffused to the side wall oxidation film due to the oxidation process.

Therefore, due to ions that are diffused from the region where ions for controlling the threshold voltage are implanted to the side wall oxidation film, the region where the ions for controlling the threshold voltage are implanted has an uneven ion concentration distribution. As a result, the uneven ion concentration distribution causes a hump phenomenon, and in turn, this causes an inverse narrow width effect that the threshold voltage becomes low, so that a problem happens in which a performance of a device may be deteriorated.

### SUMMARY OF THE INVENTION

The present invention is contrived to solve the above problems. The present invention is directed to a method of forming a device isolation film in a semiconductor device in which a performance of a device can be improved by making a constant ion concentration distribution of a region where ions for controlling a threshold voltage are implanted.

One aspect of the present invention is to provide a method of forming a device isolation film in a semiconductor device, comprising the steps of: performing an ion implantation for controlling a threshold voltage on a surface of a semiconductor substrate; forming a trench to define an active region and a device isolation region by performing a photolithography process on the semiconductor substrate; performing an oxidation process for extremely prohibiting ions, which are implanted to control the threshold voltage, from diffusing to the device isolation region and forming a side wall oxidation film at the side wall of the trench; performing an ion implantation on the active region to compensate for ions for controlling the threshold voltage, which are diffused from the active region to the side wall oxidation film by the oxidation process; and forming a device isolation film by burying the oxidation film inside the trench.

In the aforementioned of a method of forming a device isolation film in a semiconductor device according to another embodiment of the present invention, when forming the trench, the side wall oxidation film is formed to perform a rounding treatment on an upper portion or a bottom corner of the trench and to increase an adhesive strength of the oxidation film to be buried inside the trench, at the same time, and the film is formed to a thickness in the range of about 50 Å to 100 Å.

In the aforementioned of a method of forming a device isolation film in a semiconductor device according to another embodiment of the present invention, the oxidation process is performed by a dry oxidation method at a temperature in the range of about 800° C. to 950° C.

In the aforementioned of a method of forming a device isolation film in a semiconductor device according to another embodiment of the present invention, the ion implantation process performed on an active region after the oxidation process is performed by a doze of 1E11 ion/cm² to 1E12 ion/cm² in an energy band of 10Kev to 25Kev.

In the aforementioned of a method of forming a device isolation film in a semiconductor device according to another embodiment of the present invention, boron is used as an ion that is implanted for controlling the threshold voltage.

### BRIEF DESCRIPTION OF THE DRAWINGS

The aforementioned aspects and other features of the present invention will be explained in the following description, taken in conjunction with the accompanying drawings, wherein:

FIGS. 1 to 5 are cross-sectional views for explaining a method of forming a device isolation film in a semiconductor device according to a preferred embodiment of the present invention.

### DETAILED DESCRIPTION OF PREFERRED EMBODIMENTS

The present invention will be described in detail by way of a preferred embodiment with reference to accompanying drawings. However, the preferred embodiments of the present invention can be modified in various kinds of form, and the scope of the present invention should not be analyzed as limited by the following specified embodiments. The preferred embodiments of the present invention are provided to explain more clearly the present invention to those having ordinary skill in the art of the present invention. Therefore, a thickness, etc., of a film in drawings are exaggerated to explain more clearly, and like reference numerals in drawings are used to identify the same or similar parts. Also, in the specification, the phrase that a certain film is on another film or on a semiconductor substrate means that the certain film may directly contact the another film or the semiconductor substrate, or otherwise a third film may be interposed between them.

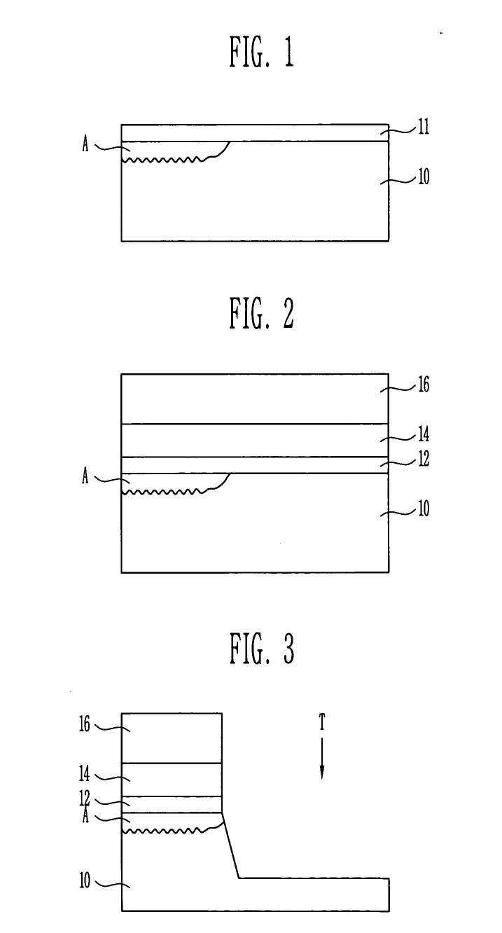

FIGS. 1 to 5 are cross-sectional views for explaining a method of forming a device isolation film in a semiconductor device according to a preferred embodiment of the present invention.

Referring now to FIG. 1, a screen oxidation film 11 is formed on an entire upper surface of a semiconductor substrate 10.

The semiconductor substrate 10 is divided into a region (hereinafter, referred to as a “PMOS region”) in which a P-type transistor is formed and another region (hereinafter, referred to as an “NMOS region”) on which an N-type transistor is formed. The screen oxidation film (not shown) functions as a buffer layer to reduce the damage in an ion implantation process performed later. At this time, the screen oxidation film (not shown) is formed by a wet oxidation method or a dry oxidation method up to a thickness in the range of about 50 Å to 70 Å at a temperature in the range of about 700° C. to 900° C.

Next, an ion implantation process is performed to form a well region and control a threshold voltage in each of the PMOS and NMOS regions by using a photolithography process. FIG. 1 illustrates an active region (A), that is, a region on which ions are implanted to control a threshold voltage in the NMOS region. Arsenic (As) or phosphorus (P) is used as an ion implantation dopant for controlling a threshold voltage in the PMOS region, and boron (B) is used as an ion implantation dopant for controlling a threshold voltage in the NMOS region. Next, the screen oxidation film 11 is removed by an etching process.

Referring now to FIG. 2, on the entire upper surface of the semiconductor substrate 10 in which the aforementioned process is completed, a gate oxidation film 12, a polysilicon film 14 and a pad nitride film 16 are formed sequentially.

The gate oxidation film 12 can be formed up to a thickness in the range of about 500 Å to 700 Å by performing an annealing process for 20 to 30 minutes by using N₂ gas at a temperature of about 900° C. to 910° C. after performing a dry or a wet oxidation process at a temperature of about 750° C. to 850° C.

The polysilicon film 14 may be formed by depositing a doped poly silicon film up to a thickness in the range of about 250 Å to 500 Å under a pressure of about 0.1 to 3 torr in an atmosphere of a PH₃ gas and a Si source gas such as SiH₄ or Si₂H₆ at a temperature of about 500° C. to 550° C.

Further, a pad nitride film 16 may be formed to a thickness of about 900 Å to 2000 Å by a low pressure chemical vapor deposition (hereinafter, referred to as an “LP-CVD”) method.

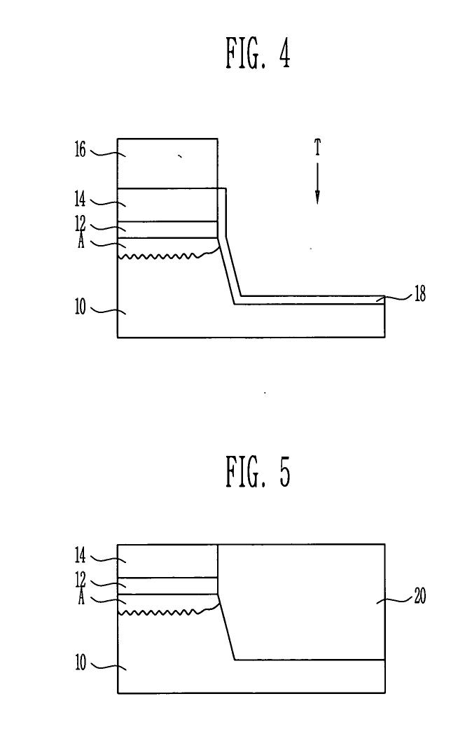

Referring now to FIG. 3, a photoresist pattern (not shown) is formed on an upper portion of the resultant, and then a trench (T) is formed to define a device isolation region by performing an etching process using the photoresist pattern as a mask (not shown).

At the time of forming the trench (T), an etching is performed so that the semiconductor substrate 10 has a specific slope of about 75° or 85°.

Referring now to FIG. 4, a side wall oxidation film 18 of is formed through an oxidation process in the side wall of the trench (T). The side wall oxidation film 18 is formed to compensate for the etching damage occurring against the side wall during the etching process for forming the trench (T) and improve the adhesive strength of the oxidation film which is buried at the inside of the trench (T) while a rounding treatment is performed on the upper portion or the bottom corner of the trench (T). At this time, the side wall oxidation film 18 can be formed up to a thickness of about 50 to 100 Å by a dry oxidation method at a temperature of about 800° C. to 950° C. In the prior art, an oxidation process for forming the side wall oxidation film of the prior art is performed at the temperature of about 1000° C. to 1150° C., thus, boron ions implanted for controlling a threshold voltage in the NMOS region drop the density of ions for controlling a threshold voltage by diffusing to the side wall oxidation film 18. However, in the present invention, by lowering to the temperature of about 800° C. to 950° C. at the process, it is possible to preventing boron ions implanted for controlling the threshold voltage from diffusing to the side wall oxidation film 18.

Referring now to FIG. 5, in order to compensate for boron ions, which are diffused to the side wall oxidation film 18 from the active region (A) through the oxidation process, an ion implantation process is performed on the active region (A) that is formed in the resultant. Due to the amount of boron ions that are diffused is reduced due to the lowered temperature of the oxidation process, it is difficult to completely prevent the diffusion of boron ions. Therefore, in order to compensate for boron ions that are diffused due to the oxidation process, an ion implantation process is performed on the active region. The ion implantation process of this time may be performed with a dose of 1E 11 to 1E12 ion/cm² having an energy band of 10 to 25 Kev. The pad nitride film 16 is removed by a wet etching process, and a device isolation film 20 is formed by performing a planarization process such as a chemical mechanical polishing (CMP) process etc. A High Density plasma (HDP) oxidation film having a superior gap fill property is deposited to be filled inside the trench (T) of the resultant. And then, the pad nitride film 16 is removed, until the polysilicon film 14 is exposed.

According to the preferred embodiment of the present invention, the process temperature is lowered through the oxidation process to form the side wall oxidation film to the trench, and the ion implantation process is performed to compensate for ions which are diffused to the side wall oxidation film at the oxidation process, so that the ion concentration distribution of the active region on which ions for controlling a threshold voltage are implanted can be constant, whereby a performance of a device can be improved.

As reviewed in the foregoing, according to the present invention, by lowering the process temperature through the oxidation process to form the side wall oxidation film to the trench, and performing an ion implantation process for compensating for ions which are diffused to the side wall oxidation film at the oxidation process, the ion concentration distribution of the active region in which ions for controlling a threshold voltage are implanted can be constant, whereby it is possible to obtain the effect that a performance of a device is improved.

Although the foregoing description has been made with reference to the preferred embodiments, it is to be understood that changes and modifications of the present invention may be made by the ordinary skilled in the art without departing from the spirit and scope of the present invention and appended claims.

What is claimed is:

1. A method of forming a device isolation film in a semiconductor device, comprising the steps of:
performing an ion implantation for controlling a threshold voltage on a surface of a semiconductor substrate;
forming a trench to define an active region and a device isolation region by performing a photolithography process on the semiconductor substrate;
performing an oxidation process for extremely prohibiting ions, which are implanted to control the threshold voltage, from diffusing to the device isolation region and forming a side wall oxidation film at the side wall of the trench;
performing an ion implantation on the active region to compensate for ions for controlling the threshold voltage, which are diffused from the active region to the side wall oxidation film by the oxidation process; and
forming a device isolation film by burying the oxidation film inside the trench.

2. The method of claim 1, wherein, when forming the trench, the side wall oxidation film is formed to perform a rounding treatment on an upper portion or a bottom corner of the trench and to increase an adhesive strength of the oxidation film to be buried inside the trench, at the same time, and the film is formed to a thickness in the range of about 50 Å to 100 Å.

3. The method of claim 1, wherein the oxidation process is performed by a dry oxidation method at a temperature in the range of about 800° C. to 950° C.

4. The method of claim 1, wherein the ion implantation process performed on an active region after the oxidation process is performed by a doze of 1E 11 ion/cm² to 1E12 ion/cm² in an energy band of 10 Kev to 25 Kev.

5. The method of claim 1, wherein boron is used as an ion that is implanted for controlling the threshold voltage.
